(19) United States
(12) Patent Application Publication
(10) Pub. No.: US 2005/0218951 A1
(43) Pub. Date: Oct. 6, 2005

(54) Flip-flop circuit and frequency division circuit using same

(75) Inventor: Shinichi Osako, Takatsuki-shi (JP)

Correspondence Address: STEPTOE & JOHNSON LLP, 1330 CONNECTICUT AVENUE, N.W., WASHINGTON, DC, 20036, US

(73) Assignee: Matsushita Elec Ind. Co., Ltd., Kadoma-shi (JP)

(21) Appl. No.: 11/089,337

(22) Filed: Mar. 25, 2005

(30) Foreign Application Priority Data
Mar. 31, 2004 (JP) 2004-104171

(51) Int. Cl. H03K 3/289

(52) U.S. Cl. 327/215

(57) ABSTRACT

An object of the present invention is to obtain a frequency division circuit including a flip-flop circuit capable of low-voltage and high-frequency operation. The frequency division circuit has bipolar transistors and MOS transistors. Thus, the circuit includes transistors that are connected to the transistor to which the clock input is input, that execute the differential operation after being input with data input signals, and that output signals of resistors, and also transistors that are similarly connected to the transistor to which Ck is input and that hold signals of resistors, transistors that are connected to the transistor to which Ck is input and that output signals of resistors, and transistors that are connected to the transistor to which NCk is input and that hold signals of resistors.

### BACKGROUND OF THE INVENTION

1. Field of the Invention

The present invention relates to a frequency division circuit using a flip-flop circuit combining therein bipolar transistors and MOS transistors and a buffer circuit.

2. Description of the Related Art

FIG. 2 shows a conventional frequency division circuit comprising a flip-flop circuit 21 using bipolar transistors and a buffer circuit 22. The reference numerals 211-228 stand for bipolar transistors, 231—a power source voltage terminal, 201-204—load resistors, 205-208—resistors determining the current of a constant current source. Pairs of transistor 211 and transistor 214, transistor 212 and transistor 213, transistor 215 and transistor 218, transistor 216 and transistor 217, transistor 221 and transistor 222, and transistor 223 and transistor 224 form respective differential pairs. A data signal D is inputted to the base of the bipolar transistor 211, and a data signal ND is inputted to the base of the bipolar transistor 214. As for the clock signals Ck and NCk, the clock signal Ck is inputted to the bipolar transistors 222, 223, and the clock signal NCk is inputted to the bipolar transistor 221, 224.

The operation principle will be described below. When a HIGH signal is inputted as a clock signal to a clock input terminal 234 (clock signal LOW is inputted to the clock input terminal 235), the bipolar transistors 221, 224 are switched ON and the differential pair formed by the bipolar transistors 211, 214 and the differential pair formed by the bipolar transistors 216, 217 become operative. Owing to the operation of the differential pair formed by the bipolar transistors 211, 214, the output of the load resistors 201, 202 is outputted in response to signals of data signals D, ND inputted to the data input terminals 232, 233. The output data of the load resistors 201, 202 are inputted to the differential pair formed by the bipolar transistors 215, 218. The operation of the bipolar transistors 215, 218 is OFF, the operation of the bipolar transistors 216, 217 is ON, and the output signal of the load resistors 203, 204 holds the data preceding the input of the clock signals to the clock input terminals 234, 235.

When a HIGH signal is inputted as a clock signal to a clock signal input terminal 235 (clock signal LOW is inputted to the clock input terminal 234), the bipolar transistors 222, 223 are switched ON and the differential pair formed by the bipolar transistors 212, 213 and the differential pair formed by the bipolar transistors 215, 218 become operative. Owing to the operation of the differential pair formed by the bipolar transistors 212, 213, the output of the load resistors 201, 202 holds the previous output state. The output signals of the load resistors 201, 202 are inputted to the differential pair formed by the bipolar transistors 215, 218. The operation of the bipolar transistors 215, 218 is ON, the operation of the bipolar transistors 216, 217 is OFF, and the output signal of the load resistors 203, 204 is outputted in response to the clock signals inputted from the clock input terminals 234, 235 and data signals outputted from the load resistors 201, 202.

Furthermore, when the output terminal of the frequency division circuit does not shift the level of the output signal voltage, output terminals 241, 242 are used. When the output voltage of the flip-flop circuit 21 is level shifted and outputted, the output voltage is shifted and outputted by using the buffer circuit 22. This buffer circuit 22 comprises bipolar transistors 219, 220, 227, 228 with a short delay time.

In the case of a bipolar transistor three-stage structure shown in FIG. 2, the base-emitter voltage Vbe of each transistor is 0.7 V, the base-collector voltage Vbc is 0.1 V, and when the voltage applied to the load resistor of the flip-flop circuit is taken as 0.3 V, the minimum necessary power source voltage becomes 0.7×3+0.1×3+0.3=2.7 V. As a result, the flip-flop circuit 21 with the bipolar transistor three-stage structure is inadequate for low-voltage operation.

FIG. 3 shows a conventional frequency division circuit comprising a flip-flop circuit 31 using MOS transistors and a buffer circuit 32. The reference numerals 311-328 stand for MOS transistors and the reference numerals 301-304 stand for load resistors. Pairs of MOS transistor 311 and MOS transistor 314, MOS transistor 312 and MOS transistor 313, MOS transistor 315 and MOS transistor 318, MOS transistor 316 and MOS transistor 317, MOS transistor 321 and MOS transistor 322, and MOS transistor 323 and MOS transistor 324 form respective differential pairs. A data signal D is inputted to the base of the MOS transistor 311, and a data signal ND is inputted to the base of the MOS transistor 314. As for the clock signals Ck and NCk, the clock signal Ck is inputted to the MOS transistors 322, 323, and the clock signal NCk is inputted to the bipolar transistor 321, 324.

The operation principle will be described below. When a HIGH signal is inputted as a clock signal to a clock input terminal 334 (clock signal LOW is inputted to the clock input terminal 335), the MOS transistors 321, 324 are switched ON and the differential pair formed by the MOS transistors 311, 314 and the differential pair formed by the MOS transistors 316, 317 become operative. Owing to the operation of the differential pair formed by the MOS transistors 311, 314, the output of the load resistors 301, 302 is outputted in response to signals of data signals D, ND inputted to the data input terminals 332, 333. The output data of the load resistors 301, 302 are inputted to the differential pair formed by the MOS transistors 315, 318. The operation of the MOS transistors 315, 318 is OFF, the operation of the MOS transistors 316, 317 is ON, and the output signal of the load resistors 303, 304 holds the data preceding the input of the clock signals to the clock input terminals 334, 335.

When a HIGH signal is inputted as a clock signal to a clock signal input terminal 335 (clock signal LOW is inputted to the clock input terminal 334), the MOS transistors 322, 323 are switched ON and the differential pair formed by the MOS transistors 312, 313 and the differential pair formed by the MOS transistors 315, 318 become operative. Owing to the operation of the differential pair formed by the MOS transistors 312, 313, the output of the load resistors 301, 302 holds the previous output state. The output signals of the load resistors 301, 302 are inputted to the differential pair formed by the MOS transistors 315, 318. The operation of the MOS transistors 315, 318 is ON, the operation of the MOS transistors 316, 317 is OFF, and the output signal of the load resistors 303, 304 is outputted in response to the clock signals inputted from the clock input terminals 334, 335 and data signals outputted from the load resistors 301, 302.

Furthermore, when the output terminal of the frequency division circuit does not shift the level of the output signal voltage, output terminals 341, 342 are used. When the output voltage of the flip-flop circuit 31 is level shifted and outputted, the output voltage is shifted and outputted by using the buffer circuit 32. This buffer circuit comprises MOS transistors 319, 320, 327, 328.

In the case of a MOS transistor three-stage structure shown in FIG. 3, the minimum required source voltage becomes lower than that of the configuration using bipolar transistors. In particular, the minimum required source voltage of a MOS with a low threshold voltage decreases and the flip-flop circuit 31 is suitable for low-voltage operation. However, because MOS transistors have a frequency characteristic worse that that of the bipolar transistors, the operation frequency decreases.

Further, because MOS transistors are provided in the buffer circuit 32, the delay time of input and output signals of the buffer circuit 32 becomes much longer than that of the buffer circuit 22 comprising bipolar transistors.

A flip-flop circuit of another embodiment disclosed in Japanese Patent Application Laid-open No. H9-69759A (shown in FIG. 4) was suggested as a frequency division circuit comprising a flip-flop circuit using bipolar transistors and capable of operating at a low voltage.

The conventional circuit shown in FIG. 4 constitutes a latch circuit comprising a first transistor differential pair Q1-Q3, a second transistor differential pair Q4-Q6, first and second load resistors R11, R12, and constant current sources Q13, R19, Q14, R20. Similarly, another latch circuits is composed of a third transistor differential pair Q7-Q9, fourth transistor differential pair Q10-Q12, third and fourth load resistors R13, R14, and constant current sources Q15, R22, Q16, and R21. This conventional flip-flop circuit reads the data of data input D, D bar when a clock input T is HIGH and outputs the read-out data to Q and Q bar when the clock input T is LOW.

In this conventional circuits, the transistors Q1, Q4, Q7, and Q10 into which the clock signals are inputted and the emitters of transistors Q2, Q3, Q5, Q6, Q8, Q11, and Q12 into which the data input signals are inputted are connected via emitter return resistors R15-R18 to conduct switching. As a result, the number of stacking stages of transistors Q1-Q12 and Q13-Q16 connected between the power source and GND is reduced by one. Reducing by one the number of transistor stages between the power source and GND enables the low-voltage operation.

In the conventional flip-flop circuit 21 using bipolar transistors shown in FIG. 2, the minimum necessary power source voltage is high, making the circuit inadequate for low-voltage operation. Furthermore, the conventional flip-flop circuit 31 using MOS transistors shown in FIG. 3 is adequate for low-voltage operation, but the operation frequency in the frequency characteristic decreases with respect to that of the flip-flop circuit using bipolar transistors. Furthermore, in the conventional example shown in FIG. 4, in order to produce a low-voltage flip-flop circuit comprising only bipolar transistors, the clock signal input uses the output of the differential circuit and the flip-flop circuit itself has a folded-type structure. Therefore, the electric current apparently increases over that of a three-stage longitudinally stacked structure of transistors.

### SUMMARY OF THE INVENTION

The present invention was achieved to resolve the above-described problems and it is an object thereof to obtain a flip-flop circuit suitable for low-voltage operation and having a high operation frequency and a frequency division circuit using such flip-flop circuit.

In order to attain the above-described object the flip-flop circuit in accordance with the present invention has a three-stage configuration of transistors connected between the power source voltage and GND, this configuration being identical to the conventional configuration. In this configuration, using bipolar transistors for the upper-stage transistors of the three-stage structure enables the circuit to operate in a frequency range up to a high frequency, and using MOS transistors with a low threshold for the transistors of the medium and lower stages of the three-stage structure of the flip-flop circuit ensures low-voltage operation.

The flip-flop circuit of the first invention comprises a MOS transistor (121) to which a clock input NCk shown in FIG. 1 is input, bipolar transistors (111, 114) having emitters thereof commonly connected to the MOS transistor, executing a differential operation after being input with data input signals (D, ND), and outputting signals of load resistors (101, 102), a MOS transistor (122) to which a clock input (Ck) is input, bipolar transistors (112, 113) having emitters thereof commonly connected to this MOS transistor, executing a differential operation after being input with output signals of load resistors (101, 102), and holding the signals of load resistors (101, 102), a MOS transistor (123) to which a clock input (Ck) is input, bipolar transistors (115, 118) having emitters thereof commonly connected to this MOS transistor, executing a differential operation after being input with output signals of load resistors (101, 102), and outputting signals of load resistors (103, 104), a MOS transistor (124) to which a clock input (NCk) is input, and bipolar transistors (116, 117) having emitters thereof commonly connected to this MOS transistor, executing a differential operation after being input with output signals of load resistors (103, 104), and holding the signals of load resistors (103, 104).

In the flip-flop circuit of the second invention, the layout of transistors of each pair in four sets of bipolar transistors (111, 112), (113, 114), (115, 116), (117, 118) forming differential pairs is such that they have common collector electrodes.

A MOS transistor with a low threshold is comprised as the MOS transistor comprised in the flip-flop circuit of the third invention.

The frequency division circuit of the fourth invention comprises the flip-flop circuit of the first to third inventions and a buffer circuit comprising bipolar transistors (119, 120) and has MOS transistors (127, 128) in the current sources.

The frequency division circuit comprising the flip-flop circuit in accordance with the present invention and the buffer circuit enables low-voltage and high-frequency operation.

### BRIEF DESCRIPTION OF THE DRAWINGS

FIG. 1 is a circuit diagram of a flip-flop circuit and a frequency division circuit of one embodiment of the present invention;

FIG. 2 is a circuit diagram of a conventional flip-flop circuit using bipolar transistors;

FIG. 3 is a circuit diagram of the conventional flip-flop circuit using MOS transistors; and

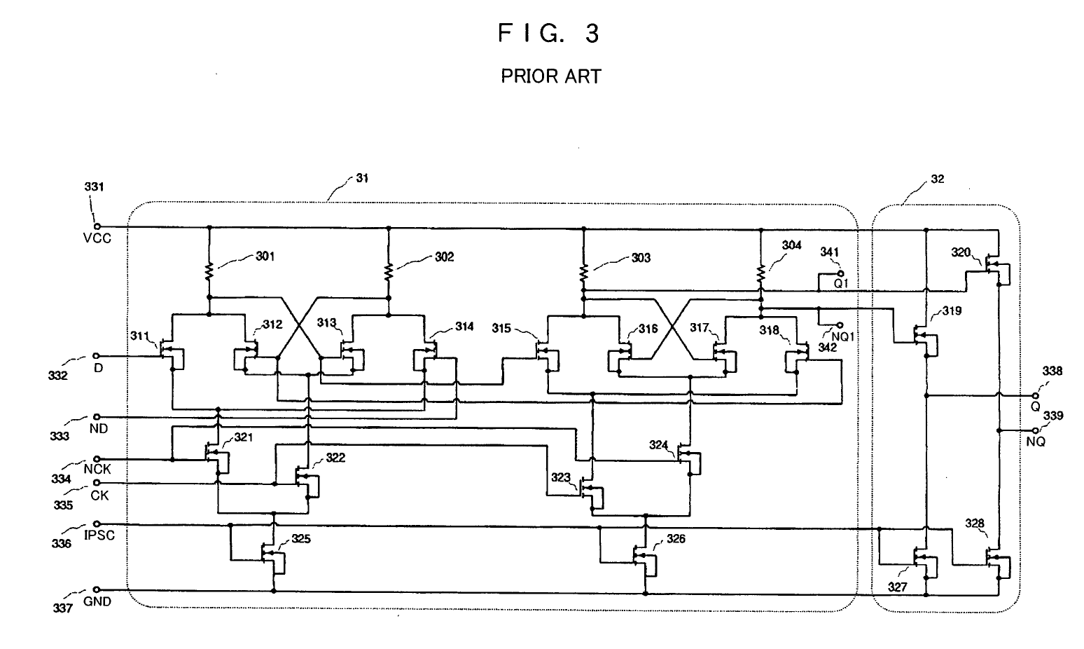

FIG. 4 is a circuit diagram of another conventional flip-flop circuit using bipolar transistors.

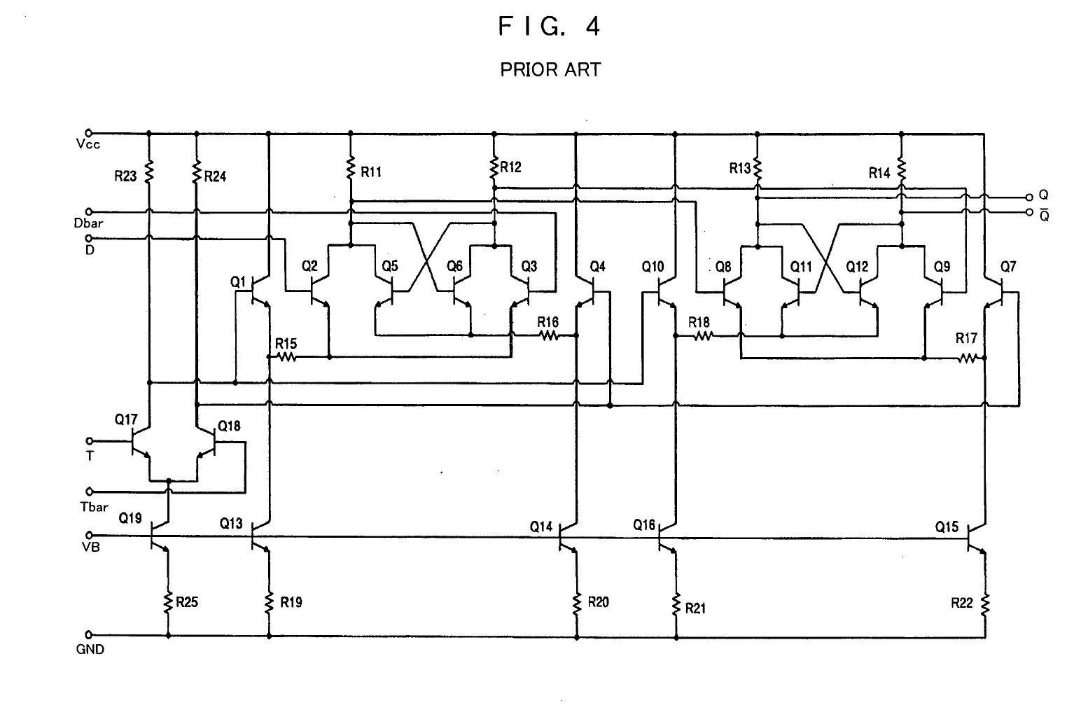

### DESCRIPTION OF THE PREFERRED EMBODIMENTS

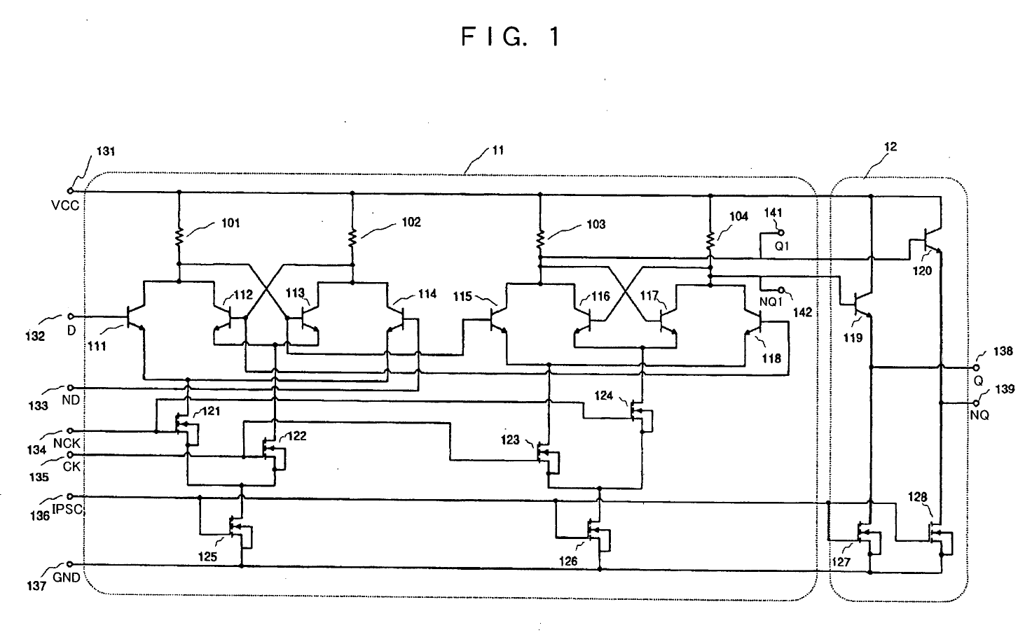

The preferred embodiments of the present invention will be described below with reference to FIG. 1.

FIG. 1 is a structural drawing illustrating a frequency division circuit of the embodiment of the present invention, this circuit comprising a flip-flop circuit 11 and a buffer circuit 12. Referring to FIG. 1, the reference numerals 101-104 stand for load resistors, 111-120—bipolar transistors, 121-128—MOS transistors. The MOS transistors 121-128 comprise low-threshold MOS transistors.

The flip-flop circuit 11 is produced by connecting the load resistors 101-104, bipolar transistors 111-118, and MOS transistors 121-126 as shown in FIG. 1. The buffer circuit 12 is provided by connecting the bipolar transistors 119, 120 and MOS transistors 127, 128 as shown in FIG. 1.

The bipolar transistor 111 and bipolar transistor 114, bipolar transistor 112 and bipolar transistor 113, bipolar transistor 115 and bipolar transistor 118, bipolar transistor 116 and bipolar transistor 117, MOS transistor 121 and MOS transistor 122, and MOS transistor 123 and MOS transistor 124 represent differential pairs.

The bipolar transistor 111 and bipolar transistor 112, bipolar transistor 113 and bipolar transistor 114, bipolar transistor 115 and bipolar transistor 116, and bipolar transistor 117 and bipolar transistor 118 have common collectors, and load resistors 101-104 are connected between a power source voltage terminal 131 and respective common collectors.

Further, a data input terminal 132 is connected to the base of the bipolar transistor 111, and the data input terminal 133 is connected to the base of the bipolar transistor 114. Furthermore, the emitter of the bipolar transistor 111 and the emitter of the bipolar transistor 114 are connected, and the emitter of the bipolar transistor 112 and the emitter of the bipolar transistor 113 are connected. The base of the bipolar transistor 112 is connected to the collector of the bipolar transistor 113 (114) and the base of the bipolar transistor 118. The base of the bipolar transistor 113 is connected to the collector of the bipolar transistor 111 (112) and the base of the bipolar transistor 115.

Further, the emitter of the bipolar transistor 115 and the emitter of the bipolar transistor 118 are connected, and the emitter of the bipolar transistor 116 and the emitter of the bipolar transistor 117 are connected. Furthermore, the base of the bipolar transistor 116 is connected to the base of the collector of the bipolar transistor 117 (118), and the base of the bipolar transistor 117 is connected to the base of the collector of the bipolar transistor 115 (116). Further, the collector of the bipolar transistor 115 (116) is connected to an output terminal 141, and the collector of the bipolar transistor 117 (118) is connected to the output terminal 142.

The drain of the MOS transistor 121 is connected to the emitter of the bipolar transistor 111 (114), the gate of the MOS transistor 121 is connected to the clock input terminal 134, the drain of the MOS transistor 122 is connected to the emitter of the bipolar transistor 112 (113), the gate of the MOS transistor 122 is connected to the clock input terminal 135, and the MOS transistor 121 and MOS transistor 122 have common sources.

Furthermore, the drain of the MOS transistor is connected to the emitter of the bipolar transistor 115 (118), the gate of the MOS transistor 123 is connected to the clock input terminal 135, the drain of the MOS transistor 124 is connected to the emitter of the bipolar transistor 116 (117), the gate of the MOS transistor 124 is connected to the clock input terminal 134, and the MOS transistor 123 and MOS transistor 124 have common sources.

Gates of the MOS transistor 125 and MOS transistor 126 are connected to a bias terminal 136 of a low-current source, the drain of the MOS transistor 125 is connected to the source of the MOS transistor 121 (122), the drain of MOS transistor 126 is connected to the source of the MOS transistor 123 (124), and the sources of the MOS transistor 125 and MOS transistor 126 are connected to a GND terminal 137.

In the buffer circuit 12, the collectors of the bipolar transistor 119 and bipolar transistor 120 are connected to the power source voltage terminal 131, the collector of the bipolar transistor 115 (116) is connected to the base of the bipolar transistor 120, the collector of the bipolar transistor 117 (118) is connected to the base of the bipolar transistor 119, the emitter of the bipolar transistor 119 is connected to the output terminal 138 and the drain of the MOS transistor 127, and the emitter of the bipolar transistor 120 is connected to the output terminal 139 and the drain of the MOS transistor 128.

Further, the bias terminal 136 of the low-current source is connected to the gate of the MOS transistor 127, 128, and the sources of MOS transistor 127 and MOS transistor 128 are connected to the GND 137.

Thus, in the present embodiment the differential pair of the bipolar transistors 111, 114, the differential pair of the bipolar transistors 112, 113, the differential pair of bipolar transistors 115, 118, and the differential pair of bipolar transistors 116, 117 comprise bipolar transistors of a differential model with a common collector electrode, thereby reducing the parasitic capacitance of the collector. The MOS transistors 125-128 are the current sources.

The operation principle is described below. When a HIGH signal is inputted as a clock signal to a clock signal input terminal 134 (clock signal LOW is inputted to the clock input terminal 135), the bipolar transistors 121, 124 are switched ON and the differential pair formed by the bipolar transistors 111, 114 and the differential pair formed by the bipolar transistors 116, 117 become operative. Owing to the operation of the differential pair formed by the bipolar transistors 111, 114, the output of the load resistors 101, 102 is outputted in response to signals of data signals D, ND inputted to the data input terminals 132, 133. The output data of the load resistors 101, 102 are inputted to the differential pair formed by the bipolar transistors 115, 118. The operation of the bipolar transistors 115, 118 is OFF, the operation of the bipolar transistors 116, 117 is ON, and the output signal of the load resistors 103, 104 holds the data preceding the input of the clock signals to the clock input terminals 134, 135.

When a HIGH signal is inputted as a clock signal to a clock signal input terminal 135 (clock signal LOW is inputted to the clock input terminal 134), the bipolar transistors 122, 123 are switched ON and the differential pair formed by the bipolar transistors 112, 113 and the differential pair formed by the bipolar transistors 115, 118 become operative. Owing to the operation of the differential pair formed by the bipolar transistors 112, 113, the output of the load resistors 101, 102 holds the previous output state. The output signals of the load resistors 101, 102 are inputted to the differential pair formed by the bipolar transistors 115, 118. The operation of the bipolar transistors 115, 118 is ON, the operation of the bipolar transistors 116, 117 is OFF, and the output signal of the load resistors 103, 104 is outputted in response to the clock signals inputted from the clock input terminals 134, 135 and data signals outputted from the load resistors 101, 102.

Furthermore, when the output terminal of the frequency division circuit does not shift the level of the output signal voltage, output terminals 141, 142 are used. When the output voltage of the flip-flop circuit 11 is level shifted and outputted, the output voltage is shifted and outputted by using the buffer circuit 12. This buffer circuit 12 comprises bipolar transistors 119, 120 with a short delay time. However, the transistors of the current source comprise the MOS transistors 127, 128 for unification with the transistors of the current source of the flip-flop circuit.

The flip-flop circuit operating in the above-described manner comprises a differential pair of the bipolar transistors 111, 114, a differential pair of the bipolar transistors 112, 113, a differential pair of the bipolar transistors 115, 118, and a differential pair of the bipolar transistors 116, 117. Thus, it comprises bipolar transistors of a differential model with common collector electrode that have excellent high-frequency characteristics. As a result the parasitic capacitance of the collector is reduced. The reduction of the collector capacitance enables the operation with the output signal of the load resistance 101-104 having a higher frequency.

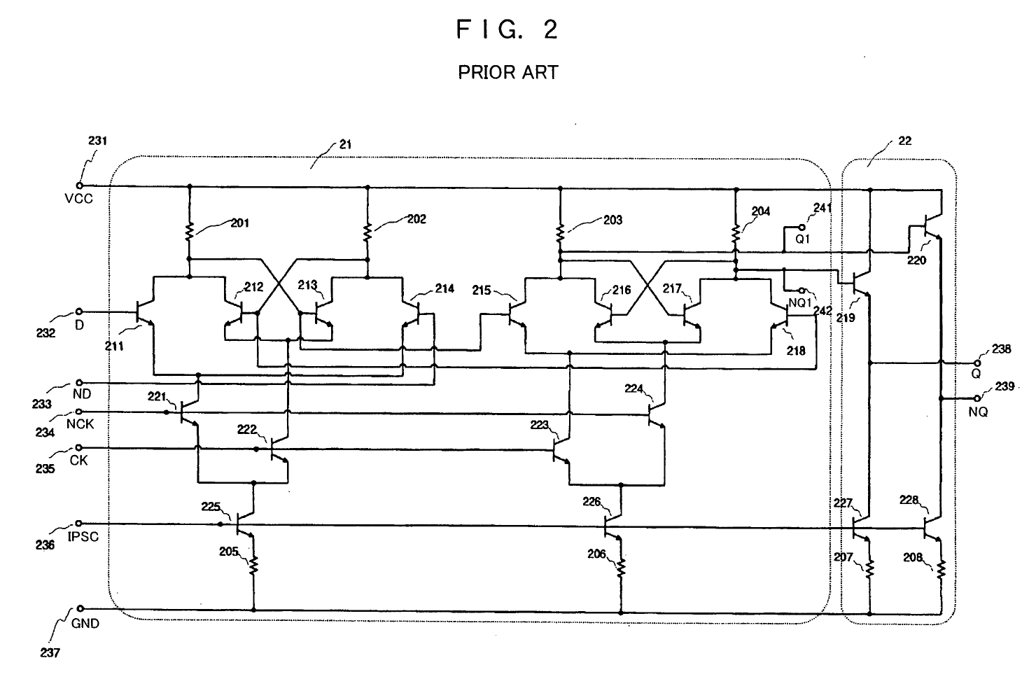

Furthermore, the MOS transistors 121-124 are provided as the inputs of the clock signals 134, 135, and MOS transistors 125-128 are provided as current sources. Thus, low-threshold MOS transistors are provided. As a result, the operation is possible at a minimum necessary power source voltage which is lower that that of the structure using only bipolar transistors, as in the conventional example shown in FIG. 2.

Thus, employing bipolar transistors of a differential model and low-threshold MOS transistors and using a structure in which the transistors are stacked in three stages makes it possible to realize a frequency division circuit comprising the flip-flop circuit 11 capable of operating at a low power voltage and providing for a high frequency characteristic and a buffer circuit 12.

As explained hereinabove, the present invention provides a frequency division circuit comprising a flip-flop circuit and suitable for low-voltage and high-frequency operation.

1. A flip-flop circuit, comprising:
bipolar transistors comprising a group of transistors including transistors for receiving a data signal input, and collector terminals connected to load resistors; and
MOS transistors comprising transistors for receiving clock signals, and transistors of current sources.

2. The flip-flop circuit according to claim 1, wherein four differential pairs are formed by said transistor groups and the transistors of each differential pair have common collector electrodes.

3. The flip-flop circuit according to claim 1, wherein said MOS transistors are MOS transistors having a low-threshold.

4. The flip-flop circuit according to claim 2, wherein said MOS transistors are MOS transistors having a low-threshold.

5. A frequency division circuit comprising the flip-flop circuit according to claim 1 and a buffer circuit comprising a bipolar transistor being connected to the output terminal of the flip-flop circuit and inputted with output signals from the flip-flop, wherein MOS transistors are used for the transistors for the current source of said buffer circuit.

6. A frequency division circuit comprising the flip-flop circuit according to claim 2 and a buffer circuit comprising a bipolar transistor being connected to the output terminal of the flip-flop circuit and inputted with output signals from the flip-flop, wherein MOS transistors are used for the transistors for the current source of said buffer circuit.

7. A frequency division circuit comprising the flip-flop circuit according to claim 3 and a buffer circuit comprising a bipolar transistor being connected to the output terminal of the flip-flop circuit and inputted with output signals from the flip-flop, wherein MOS transistors are used for the transistors for the current source of said buffer circuit.

8. A frequency division circuit comprising the flip-flop circuit according to claim 4 and a buffer circuit comprising a bipolar transistor being connected to the output terminal of the flip-flop circuit and inputted with output signals from the flip-flop are input, wherein MOS transistors are used for the transistors for the current source of said buffer circuit.
